(19) United States
(12) Patent Application Publication
(10) Pub. No.: US 2025/0258214 A1
(43) Pub. Date: Aug. 14, 2025

(54) INSPECTION APPARATUS AND INSPECTION METHOD USING THE SAME

(71) Applicant: TOP ENGINEERING CO., LTD, Gumi-si Gyeongsangbuk-do (KR)

(72) Inventor: Kyu Yong BANG, Paju-Si (KR)

(21) Appl. No.: 18/856,346

(22) PCT Filed: Mar. 31, 2023
(86) PCT No.: PCT/KR2023/004351

§ 371 Date: Oct. 11, 2024

(30) Foreign Application Priority Data
Apr. 14, 2022 (KR) 10-2022-0046203

(51) Int. Cl. G01R 31/265

(52) U.S. Cl. CPC G01R 31/2653

(57) ABSTRACT

An embodiment discloses an inspection apparatus and an inspection method, the inspection apparatus including a stage on which a plurality of micro-light-emitting elements is disposed, an electron beam emitting unit configured to emit electron beams to the plurality of micro-light-emitting elements, an optical detection unit configured to measure light emitted from the plurality of micro-light-emitting elements, and an electron beam guide unit disposed between the electron beam emitting unit and the plurality of micro-light-emitting elements.

### TECHNICAL FIELD

Embodiments relate to an inspection apparatus and an inspection method, which are capable of inspecting a micro-light-emitting element in a contactless manner to examine whether the micro-light-emitting element is defective.

### BACKGROUND ART

Representative displays, which are currently commercially available, include a liquid crystal display (LCD) and an organic light-emitting diode (OLED). Recently, OLED displays have been actively developed. However, the OLED display has a problem in that the OLED display has a short lifespan, and a yield rate of mass-producing the OLED displays is low.

A light-emitting diode (LED) is one of the light-emitting elements that emit light by receiving electric current. The light-emitting diode has an excellent effect of saving energy because the light-emitting diode may emit light with high efficiency by using a low voltage. Recently, the brightness of the light-emitting diode has been significantly improved. Therefore, the light-emitting diodes are applied to various types of devices, such as backlight units for liquid crystal display devices, electronic display boards, indicators, and household electrical appliances.

The light-emitting diode containing compounds such as GaN and AlGaN is advantageous because the light-emitting diode has wide band gap energy that can be easily adjustable. Therefore, the light-emitting diodes may be variously used for light-emitting elements, light-receiving elements, various types of diodes, and the like. In particular, the light-emitting diode is advantageous in terms of low power consumption, a semipermanent lifespan, a high response speed, safety, and environmental-friendly properties.

Recently, there has been studied a technology for using a micro-light-emitting element, which is a light-emitting diode manufactured to have a small size, as a pixel of a display. Because a large number of micro-light-emitting elements are manufactured on a single wafer, it is important to accurately inspect the light-emitting element to examine whether the light-emitting element is defective.

However, an apparatus for inspecting a plurality of micro-light-emitting elements by allowing the plurality of micro-light-emitting elements to emit light in a contactless manner is not yet commercially available.

### DISCLOSURE

### Technical Problem

Embodiments provide an inspection apparatus capable of inspecting micro-light-emitting elements by allowing the micro-light-emitting elements to emit light in a contactless manner.

The objects to be achieved by the embodiment are not limited to the above-mentioned objects, but also include objects or effects that may be understood from the solutions or embodiments described below.

### Technical Solution

An inspection apparatus according to one aspect of the present invention includes: a stage on which a plurality of micro-light-emitting elements is disposed; an electron beam emitting unit configured to emit electron beams to the plurality of micro-light-emitting elements; an optical detection unit configured to acquire an image of light emitted from the plurality of micro-light-emitting elements; an electron beam guide unit disposed between the electron beam emitting unit and the plurality of micro-light-emitting elements; and a control unit configured to determine whether the plurality of micro-light-emitting elements is defective on the basis of the image of light acquired by the optical detection unit.

The electron beam guide unit may include a plurality of through-holes through which the electron beams pass.

A ratio between a first distance between the electron beam emitting unit and the micro-light-emitting element and a second distance between the electron beam emitting unit and the electron beam guide unit (first distance: second distance) may be 1:0.6 to 1:0.99.

The electron beam guide unit may include: a first electron beam guide unit disposed between the electron beam emitting unit and the plurality of micro-light-emitting elements; and a second electron beam guide unit disposed between the first electron beam guide unit and the plurality of micro-light-emitting elements.

The electron beam emitting unit may include: an electrode layer; a plurality of emitters formed on the electrode layer and configured to emit electrons toward the plurality of micro-light-emitting elements; and a gate electrode disposed to be spaced apart from the electrode layer, and the emitter may include a carbon nanotube.

A level of a voltage applied to the electron beam guide unit may be higher than a level of a voltage applied to the gate electrode.

The plurality of micro-light-emitting elements may each include: a first conductive semiconductor layer; a second conductive semiconductor layer; and an active layer disposed between the first conductive semiconductor layer and the second conductive semiconductor layer, and the first conductive semiconductor layer, the active layer, and the second conductive semiconductor layer may each emit light when irradiated with the electron beam.

The inspection apparatus may include: a filter configured to block some of light beams entering the optical detection unit, in which the filter transmits a first light beam emitted from the active layer and blocks a second light beam emitted from the first conductive semiconductor layer or the second conductive semiconductor layer.

The inspection apparatus may include: a filter array configured to block some of light beams entering the optical detection unit, in which the filter array includes: a first filter configured to selectively transmit a light beam in a first wavelength band among all wavelength bands of first light beams emitted from the active layers of the plurality of micro-light-emitting elements; and a second filter configured to selectively transmit a light beam in a second wavelength band different from the first wavelength band among all the wavelength bands of the first light beams, and in which the first light beam is any one of a blue light beam, a green light beam, and a red light beam.

The filter array may include a drive unit configured to selectively dispose the first filter and the second filter on the optical detection unit.

The inspection apparatus may include: a vibration unit configured to vibrate the electron beam emitting unit.

The inspection apparatus may include: a movable member configured to move the stage or the electron beam guide unit, in which the stage or the electron beam guide unit may move, such that the micro-light-emitting element, which overlaps the electron beam guide unit, may be exposed through the through-hole of the electron beam guide unit.

The inspection apparatus may include: a chamber in which the stage, the electron beam emitting unit, and the electron beam guide unit are disposed; and a vacuum pump configured to create a vacuum in the chamber.

The inspection apparatus may include: a housing configured to accommodate the electron beam emitting unit and the electron beam guide unit; and a movement module configured to move the housing, in which only some of the plurality of micro-light-emitting elements may be irradiated with the electron beams emitted from the housing. The housing may be disposed to be inclined with respect to an imaginary line perpendicular to the stage.

An inspection method according to one aspect of the present invention includes: creating a vacuum in a chamber; emitting electron beams to a plurality of micro-light-emitting elements disposed in the chamber; measuring light-emitting intensities of the plurality of micro-light-emitting elements; and determining whether the plurality of micro-light-emitting elements is defective, in which the electron beams are accelerated by an electron beam guide unit disposed between an electron beam emitting unit and the plurality of micro-light-emitting elements, and the electron beams are injected into the plurality of micro-light-emitting elements.

### Advantageous Effects

The embodiment provides the inspection apparatus capable of inspecting the micro-light-emitting elements by allowing the micro-light-emitting elements to emit light in a contactless manner, which makes it possible to increase the rate of inspection of the plurality of micro-light-emitting elements and prevent damage to the light-emitting element.

The various, beneficial advantages and effects of the present invention are not limited to the above-mentioned contents and may be more easily understood during the process of describing the specific embodiments of the present invention.

### DESCRIPTION OF DRAWINGS

FIG. 1 is a conceptual view of an inspection apparatus according to a first embodiment of the present invention.

FIG. 2 is a view illustrating a state in which electron beams are emitted, and light-emitting elements emit light.

FIG. 3 is a view illustrating the principle that the light-emitting element emits light by receiving electron beams.

FIG. 4 is a view illustrating a state in which light emitted from the light-emitting element selectively enters an optical detection unit by a filter.

FIG. 5A is a view illustrating a mesh shape of an electron beam guide unit.

FIG. 5B is a view illustrating a cross-sectional shape of the electron beam guide unit.

FIG. 5C is a view illustrating a first modified example of FIG. 5A.

FIG. 5D is a view illustrating a second modified example of FIG. 5A.

FIG. 6A is a view illustrating an electron beam emitting unit.

FIG. 6B is a view illustrating a modified example of FIG. 6A.

FIG. 7 is a view illustrating measured light-emitting intensities of a plurality of micro-light-emitting elements.

FIG. 8 is a photograph of the measured plurality of micro-light-emitting elements.

FIG. 9 is a conceptual view of an inspection apparatus according to a second embodiment of the present invention.

FIG. 10 is a conceptual view of an inspection apparatus according to a third embodiment of the present invention.

FIG. 11 is a view illustrating a filter array.

FIG. 12 is a view illustrating a state in which the filter array is rotated.

FIG. 13 is a view illustrating a process in which a filter sorts wavelengths.

FIG. 14 is a conceptual view of an inspection apparatus according to a fourth embodiment of the present invention.

FIG. 15 is a view illustrating a plurality of light-emitting elements in a state in which some of the plurality of light-emitting elements are connected.

FIG. 16 is a view illustrating a modified example of FIG. 15.

FIG. 17 is a conceptual view of an inspection apparatus according to a fifth embodiment of the present invention.

FIGS. 18A and 18B are views illustrating a process of scanning a linear inspection area.

FIG. 19 is a conceptual view of an inspection apparatus according to a sixth embodiment of the present invention.

FIG. 20 is a conceptual view of an inspection apparatus according to a seventh embodiment of the present invention.

FIG. 21 is a top plan view of an electron beam guide unit.

FIG. 22 is a view illustrating a state in which the electron beam guide unit is moved.

FIG. 23 is a flowchart illustrating an inspection method according to one embodiment of the present invention.

FIG. 24A is a view illustrating a state in which an electron beam measurement unit measures uniformity of the electron beams.

FIG. 24B is a view illustrating a state in which a first electrode layer and the electron beam measurement unit are divided into a plurality of areas.

### MODE FOR INVENTION

The present invention may be variously modified and may have various forms, and particular embodiments illustrated in the drawings will be described in detail below. However, the description of the embodiments is not intended to limit the present invention to the particular embodiments, but it should be understood that the present invention is to cover all modifications, equivalents and alternatives falling within the spirit and technical scope of the present invention.

The terms including ordinal numbers such as ‘second’, ‘first’, and the like may be used to describe various constituent elements, but the constituent elements are not limited by the terms. These terms are used only to distinguish one constituent element from another constituent element. For example, a second component may be named a first component, and similarly, the first component may also be named the second component, without departing from the scope of the present invention. The term “and/or” includes any and all combinations of a plurality of the related and listed items.

When one constituent element is described as being “coupled” or “connected” to another constituent element, it should be understood that one constituent element can be coupled or connected directly to another constituent element, and an intervening constituent element can also be present between the constituent elements. When one constituent element is described as being “coupled directly to” or “connected directly to” another constituent element, it should be understood that no intervening constituent element is present between the constituent elements.

The terminology used herein is used for the purpose of describing particular embodiments only and is not intended to limit the present invention. Singular expressions include plural expressions unless clearly described as different meanings in the context. The terms “comprises,” “comprising,” “includes,” “including,” “containing,” “has,” “having” or other variations thereof are inclusive and therefore specify the presence of stated features, integers, steps, operations, elements, components, and/or combinations thereof, but do not preclude the presence or addition of one or more other features, integers, steps, operations, elements, components, and/or combinations thereof.

Unless otherwise defined, all terms used herein, including technical or scientific terms, have the same meaning as commonly understood by those skilled in the art to which the present invention pertains. The terms such as those defined in a commonly used dictionary should be interpreted as having meanings consistent with meanings in the context of related technologies and should not be interpreted as ideal or excessively formal meanings unless explicitly defined in the present application.

Hereinafter, embodiments will be described in detail with reference to the accompanying drawings. The same or corresponding constituent elements are assigned with the same reference numerals regardless of reference numerals, and the repetitive description thereof will be omitted.

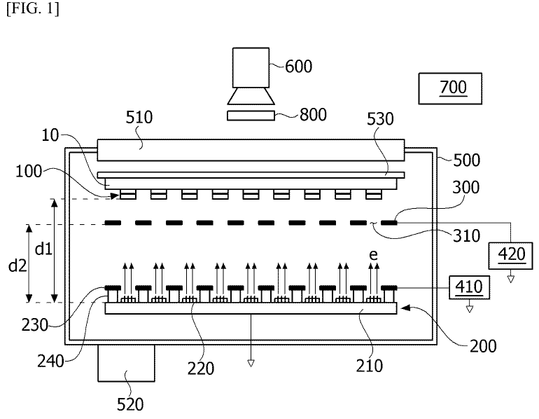

FIG. 1 is a conceptual view of an inspection apparatus according to a first embodiment of the present invention.

With reference to FIG. 1, the inspection apparatus according to the embodiment includes a stage 530 on which a plurality of micro-light-emitting elements 100 is disposed, an electron beam emitting unit 200 configured to emit electron beams to the plurality of micro-light-emitting elements 100, an electron beam guide unit 300 disposed between the electron beam emitting unit 200 and the plurality of micro-light-emitting elements 100, and a chamber 500 configured to create a vacuum therein.

The chamber 500 may accommodate the stage 530, the electron beam emitting unit 200, and the electron beam guide unit 300. The chamber 500 may create a vacuum therein and thus prevent the electron beam from scattering.

The chamber 500 may maintain a vacuum of 10⁻⁵ Torr or less. The time for which the chamber 500 may be continuously used may be, but not necessarily limited to, 10,000 hours or longer. The time for which the chamber 500 may be continuously used may be adjusted to satisfy various conditions required to emit the electron beams to the micro-light-emitting elements 100. A vacuum pump 520 may be disposed in the chamber 500 and adjust vacuum pressure in the chamber 500.

A sub-chamber (not illustrated) configured to accommodate a plurality of wafers may be further disposed in the chamber 500. A transfer member (not illustrated) configured to seat the wafer on the stage 530 may be further disposed in the chamber 500.

A substrate 10 on which the plurality of micro-light-emitting elements 100 is disposed may be fixed to the stage 530. The substrate 10 may be a sapphire (Al₂O₃) wafer that is a growth substrate. However, the present invention is not necessarily limited thereto. The substrate 10 may be various substrates on which the micro-light-emitting elements 100 are disposed. For example, the substrate 10 may be a transfer substrate to which the micro-light-emitting element 100 is transferred. Alternatively, the substrate 10 may be a display panel to which the micro-light-emitting element 100 is completely transferred.

The micro-light-emitting element 100 may be a light-emitting diode or an organic light-emitting diode having a size of 1 μm to 200 μm. For example, the size of the micro-light-emitting element 100 may be 10 μm to 60 μm, but the present invention is not necessarily limited thereto. The light-emitting elements having various sizes may be applied. For example, the micro-light-emitting element 100 may be a mini-sized light-emitting element having a size of 200 μm to 500 μm. Alternatively, the micro-light-emitting element 100 may be an RGB light-emitting element having a size of 1,000 μm or more.

The micro-light-emitting element 100 may be any one of a blue light-emitting element, a green light-emitting element, and a red light-emitting element. Because the micro-light-emitting element 100 serves as a pixel of a display, the micro-light-emitting element 100 may be designed to have any one wavelength band among RGB wavelength bands. However, the present invention is not necessarily limited thereto. The micro-light-emitting element 100 may be a white light-emitting element.

The micro-light-emitting elements 100 may be in a state in which a plurality of light-emitting structures is separated on the growth substrate. However, the present invention is not necessarily limited thereto. Some semiconductor layers may be connected to one another. That is, the micro-light-emitting elements 100 may be defined as semiconductor structures in which active layers may be separated and emit light independently.

The micro-light-emitting element 100 may be grown on the substrate using a method such as metal-organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The electron beam emitting unit 200 may include a first electrode layer 210, and a plurality of emitters 220 disposed on the first electrode layer 210 and configured to emit electrons toward the plurality of micro-light-emitting elements 100. The emitted electrons may move toward the plurality of micro-light-emitting elements. In this case, the electrons may be defined as negatively charged particles, and the electron beam may be defined as a continuous flow of electrons having kinetic energy and directionality.

The first electrode layer 210 may contain, but not necessarily limited to, Al, Ag, Cu, Ti, Pt, Ni, Ir, or Rh. For example, the first electrode layer 210 may be manufactured as a transparent electrode such as ITO.

The emitter 220 may contain, but not necessarily limited to, carbon nanotubes (CNTs). Various materials and structures capable of emitting electrons may be applied to the emitter 220.

At least some of the plurality of carbon nanotubes, which constitute the emitter 220, may each have a shape extending in a vertical direction from the first electrode layer 210 toward the stage 530. However, the present invention is not necessarily limited thereto. The plurality of carbon nanotubes may each have a shape extending in a horizontal direction.

The plurality of emitters 220 may be uniformly arranged on the first electrode layer 210. Therefore, the electrons emitted from the plurality of emitters 220 may be uniformly emitted to the plurality of micro-light-emitting elements 100.

Gate electrodes 230 may be disposed to be spaced apart from the plurality of emitters 220 by insulation layers 240. The gate electrode 230 may be disposed to be higher than the emitter 220. However, the present invention is not necessarily limited thereto. The gate electrode 230 may be disposed at various positions at which the gate electrode 230 may form an electric field together with the first electrode layer 210.

A first power source unit 410 may apply voltages to the first electrode layer 210 and the gate electrode 230. A negative voltage may be applied to the first electrode layer 210, and a positive voltage may be applied to the gate electrode 230.

The first power source unit 410 may operate with a pulse of 1 kHz or less by using a high voltage of 1,000 V to 3,000 V. When a high-voltage pulse is applied, an electric field may be formed between the first electrode layer 210 and the gate electrode 230. Therefore, the electrons emitted from the emitter 220 may move toward the micro-light-emitting element 100. Hereinafter, a configuration will be described in which electrons accelerate toward the micro-light-emitting element 100 to form electron beams.

The electron beam guide unit 300 may be disposed between the electron beam emitting unit 200 and the plurality of micro-light-emitting elements 100. The electron beam guide unit 300 may be a second gate electrode disposed to be spaced apart from the first electrode layer 210 of the electron beam emitting unit 200 and configured to form an electric field.

The second power source unit 420 may accelerate electron beams by applying a positive voltage of 8,000 V to 12,000 V to the electron beam guide unit 300. The plurality of micro-light-emitting elements 100 may be irradiated with the electron beams accelerated by the electron beam guide unit 300, such that the plurality of micro-light-emitting elements 100 may emit light.

The electron beam guide unit 300 may be disposed to be closer to the micro-light-emitting elements 100 than the electron beam emitting unit 200.

A ratio between a first distance d1 between the electron beam emitting unit 200 and the micro-light-emitting element 100 and a second distance d2 between the electron beam emitting unit 200 and the electron beam guide unit 300 (first distance:second distance) may be 1:0.6 to 1:0.99. In case that the distance ratio (e.g., 1:0.4) is smaller than 1:0.6, the distance between the electron beam guide unit 300 and the micro-light-emitting element 100 increases, and the electron beam with sufficient energy cannot enter the micro-light-emitting element 100. In addition, in case that the distance ratio is larger than 1:0.99, the electron beam guide unit 300 is too close to the micro-light-emitting element 100, which may degrade uniformity of the electron beams.

The electron beam guide unit 300 may have a plurality of through-holes 310 through which the electron beams may pass. For example, the electron beam guide unit 300 may have a mesh shape. However, the present invention is not necessarily limited thereto. The electron beam guide unit 300 may have various structures capable of transmitting the electron beams while forming the electric field capable of accelerating the electron beams. For example, the electron beam guide unit 300 may be configured as an electrode that transmits the electron beams.

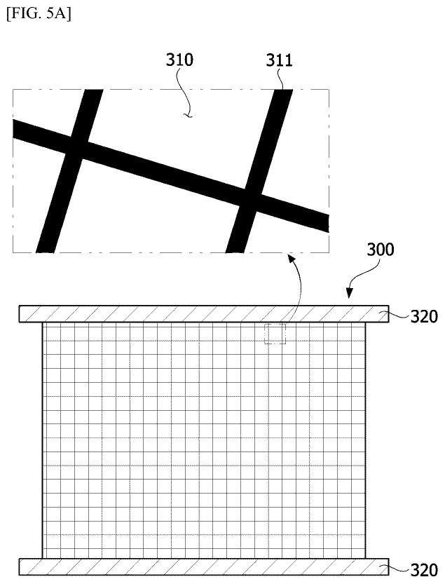

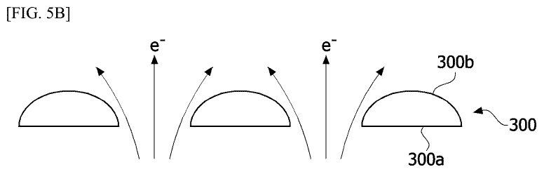

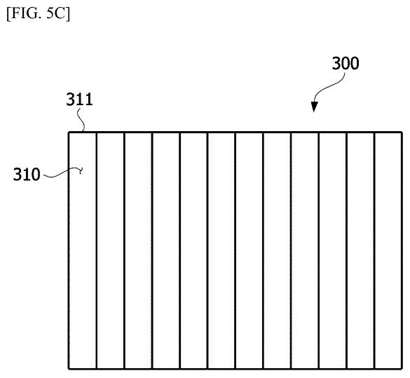

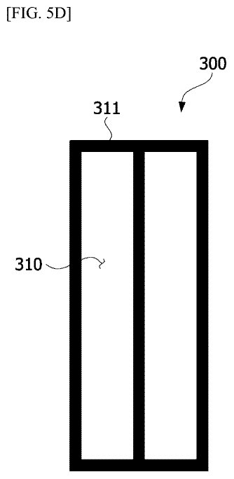

The electron beam guide unit 300 or the stage 530 may move relative to each other to improve the uniformity. Movable members (320 in FIG. 5A) may move the electron beam guide unit 300 leftward or rightward, such that the micro-light-emitting elements 100, which overlap the electron beam guide unit 300 and are covered by the electron beam guide unit 300, may be exposed through the through-holes 310 of the electron beam guide unit 300 and emit electron beams. However, the present invention is not necessarily limited thereto. The stage 530 may be moved leftward or rightward.

The electron beam guide unit 300 may have various advantages. According to the embodiment, because the electron beam guide unit 300 is disposed between the electron beam emitting unit 200 and the micro-light-emitting elements 100, it is not necessary to apply voltages to the micro-light-emitting elements 100. A structure in which a power source needs to be connected to the micro-light-emitting elements 100 may significantly complicate circuits because the power source needs to be connected to the plurality of micro-light-emitting elements 100.

In addition, a structure in which an electrode is disposed on a rear surface of the substrate 10 or the stage 530 cannot form a strong electric field, and the electron beam may not be sufficiently accelerated. For this reason, the electron beams cannot be sufficiently injected into the light-emitting elements, and sufficient light-emitting intensities cannot be implemented even though the light-emitting elements are normal.

The optical detection unit 600 may acquire images of light emitted from the plurality of micro-light-emitting elements 100. The optical detection unit 600 may be, but not necessarily limited to, a camera equipped with a CCD. Various imaging devices capable of acquiring light-emitting images of the micro-light-emitting element 100 may be applied without limitation.

The optical detection unit 600 may be disposed above a window 510 of the chamber 500 and measure light-emitting intensities of the plurality of micro-light-emitting elements 100. The light emitted from the plurality of micro-light-emitting elements 100 may pass through the substrate 10 and enter the optical detection unit 600.

However, the position of the optical detection unit 600 is not limited thereto but may be variously changed. For example, the optical detection unit 600 and the window 510 may be disposed at a lateral side of the chamber 500 or disposed below the electron beam emitting unit 200. That is, the optical detection unit 600 may be disposed at various positions at which the optical detection unit 600 may measure the light-emitting intensities of the micro-light-emitting elements 100.

The optical detection unit 600 may convert the collected light-emitting intensities (spectra) or wavelength signals into an electrical signal and transmit the electrical signal to a control unit 700. The control unit 700 may include a main processor configured to control an overall operation of the inspection apparatus.

The control unit 700 may control the operations of the electron beam emitting unit 200, the first power source unit 410, and the second power source unit 420. The control unit 700 may process measurement signals of the optical detection unit 600, output map data including a result of evaluating the micro-light-emitting elements 100, detect a defective element.

The control unit 700 may be implemented to include: a memory (not illustrated) configured to store data associated with an algorithm for controlling operations of constituent elements in the inspection apparatus or with a program for reproducing the algorithm; and a processor (not illustrated) configured to perform the above-mentioned operations by using the data stored in the memory. In this case, the memory and the processor may each be implemented as, but not necessarily limited to, a separate chip. The memory and the processor may be implemented as a single chip.

The control unit 700 may be connected to a storage unit (not illustrated) for storing processed data. The storage unit may be implemented as, but not necessarily limited to, at least one of non-volatile memory elements such as a read-only memory (ROM), a programmable ROM (PROM), an erasable programmable ROM (EPROM), an electrically erasable programmable ROM (EEPROM), and a flash memory, volatile memory elements such as a random access memory (RAM), and storage media such as a hard disc drive (HDD) or a CD-ROM.

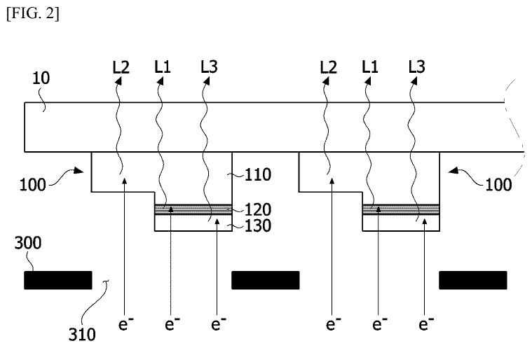

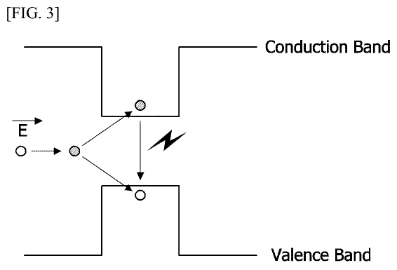

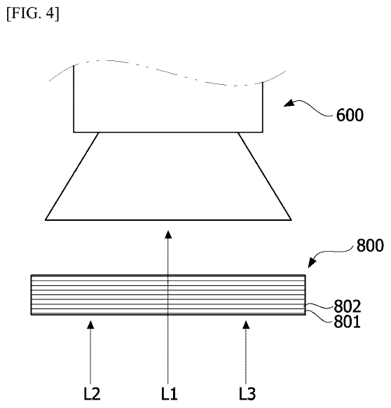

FIG. 2 is a view illustrating a state in which electron beams are emitted, and the light-emitting elements emit light, FIG. 3 is a view illustrating the principle that the light-emitting element emits light by receiving electron beams, and FIG. 4 is a view illustrating a state in which light emitted from the light-emitting element selectively enters the optical detection unit by a filter.

With reference to FIGS. 2 and 3, the micro-light-emitting element 100 may include a first conductive semiconductor layer 110, an active layer 120, and a second conductive semiconductor layer 130. The first conductive semiconductor layer 110 may be implemented as a III-V group or II-VI group compound semiconductor, and the first conductive semiconductor layer 110 may be doped with a first dopant.

The first conductive semiconductor layer 110 may be made of, but not limited to, one or more of a semiconductor material implemented on the basis of a compositional formula AlₓIn_{y}Ga_{1-x-y}N (0≤x≤1, 0≤y≤1, and 0≤x+y≤1), InAlGaN, AlGaAs, GaP, GaAs, GaAsP, and AlGaInP. In case that the first dopant is an n-type dopant such as Si, Ge, Sn, Se, or Te, the first conductive semiconductor layer 110 may be an n-type nitride semiconductor layer.

The active layer 120 may be disposed on the first conductive semiconductor layer 110. In addition, the active layer 120 may be disposed between the first conductive semiconductor layer 110 and the second conductive semiconductor layer 130.

The active layer 120 refers to a layer in which electrons (or holes) introduced through the first conductive semiconductor layer 110 meet holes (or electrons) introduced through the second conductive semiconductor layer 130. The active layer 120 undergoes a transition to a low energy level as the electrons and the holes are recombined, and thus the active layer 120 may create light having a wavelength corresponding to the energy level.

The active layer 120 may have any one of a single well structure, a multi-well structure, a single quantum well structure, a multi-quantum well (MQW) structure, a quantum dot structure, and a quantum line structure. However, the structure of the active layer 120 is not limited thereto. The active layer 120 may create light in a visible wavelength range.

The second conductive semiconductor layer 130 may be disposed on the active layer 120. The second conductive semiconductor layer 130 may be implemented as a III-V group or II-VI group compound semiconductor, and the second conductive semiconductor layer 130 may be doped with a second dopant.

The second conductive semiconductor layer 130 may be made of a material selected from a semiconductor material implemented on the basis of a composition formula Inₓ₅Al_{y2}Ga_{1-x5-y2}N (0≤x5≤1, 0≤y2≤1, and 0≤x5+y2≤1), AlInN, AlGaAs, GaP, GaAs, GaAsP, and AlGaInP. In case that the second dopant is a p-type dopant such as Mg, Zn, Ca, Sr, or Ba, the second conductive semiconductor layer 130 doped with the second dopant may be a p-type semiconductor layer.

With reference to FIGS. 2 and 3, the semiconductor layers of the micro-light-emitting elements 100 may be irradiated with the electron beams having passed through the through-holes 310 of the electron beam guide unit 300. When the electron beams are emitted to the micro-light-emitting elements 100, the electron beams may collide with one another in the semiconductor layer, such that the electron-hole pairs may be generated. The generated electron-hole pairs may be recombined to emit visible light.

The intensity of the visible light emitted from the micro-light-emitting element 100 may be proportional to the intensity (or density) of the electron beam. Therefore, the intensity (or density) of the electron beam may be adjusted to detect the light emitted from the micro-light-emitting element 100 and determine whether the micro-light-emitting element is defective.

The micro-light-emitting element 100 may be any one of a blue light-emitting element, a green light-emitting element, and a red light-emitting element. Therefore, the micro-light-emitting element 100 may emit light in a blue, green, or red wavelength range.

The electron beams injected into the micro-light-emitting elements 100 may be injected not only into the active layer 120 but also into the first conductive semiconductor layer 110 and the second conductive semiconductor layer 130. Therefore, the first conductive semiconductor layer 110 and the second conductive semiconductor layer 130 may also emit light.

For example, in case that the micro-light-emitting element 100 is the blue light-emitting element, a first light beam L1 in a blue wavelength band emitted from the active layer 120 and second light beams L2 and L3 in a yellow wavelength band emitted from the first conductive semiconductor layer 110 and the second conductive semiconductor layer 130 may be mixed, and the mixed light beams may be discharged to the outside.

With reference to FIG. 4, a filter 800 disposed forward of the optical detection unit 600 may transmit only the first light beam L1 and block the second light beams L2 and L3. Therefore, only the intensity of the first light beam L1 may be measured, such that whether the micro-light-emitting element 100 is defective may be accurately determined.

Various band pass filters capable of transmitting only the wavelength band of the first light beam L1 may be applied to the filter 800. For example, the filter 800 may be configured by alternately stacking a plurality of high refractive index layers 801 and a plurality of low refractive index layers 802 in order to transmit only light in a particular wavelength band. However, the structure of the filter 800 is not necessarily limited thereto.

The filter 800 may be selectively applied depending on the inspection method. In case that the inspection method does not use the filter and an inspection target is a blue micro-element, the inspection target may be determined as a normal element when intensities of blue light and yellow light in the detected wavelength are within predetermined range, and the inspection target may be determined as a defective element when intensities of blue light and yellow light deviate from a predetermined ratio. For example, when the intensity of blue light is significantly low, the micro-light-emitting element may be determined as being defective. The filter may be excluded in case that a defect is determined by the above-mentioned method.

The embodiment adopts a cathodoluminescence (CL) method that allows the micro-light-emitting elements 100 to emit light by emitting the electron beams. Therefore, the embodiment may quickly perform the inspection because the light emission is enabled without damaging the light-emitting element, and the plurality of micro-light-emitting elements emit light at once by being irradiated with the electron beams.

A scanning electron microscope (SEM) refers to a microscope widely used to observe a shape and fine tissue having a small size in a solid state. The scanning electron microscope (SEM) refers to an analysis device capable of observing, with high magnification, a three-dimensional shape such as a complicated surface structure or an external shape of a crystal because the scanning electron microscope has a great focal depth and facilitates observation of a three-dimensional image.

The scanning electron microscope includes an electron gun configured to generate and accelerate electron beams, a focusing lens and an objective lens configured to collect the electron beams so that the electron beams are elongated, and a deflection coil configured to adjust paths of the electron beams until the electron beams exiting a filament reach a specimen. However, the scanning electron microscope measures a chemical composition by emitting electron beams to a local area and thus differs from the present embodiment that emits electron beams to a large area.

A field emission display refers to a display in which field emission emitter arrays, which are cold cathode electron beam sources, are disposed in the form of a matrix. The field emission display emits light by emitting electron beams from a cathode to a phosphor. However, there is a difference in that the field emission display is not structured to allow the light-emitting diode to emit light.

In addition, a photoluminescence (PL) method creates light by injecting light into a sample and recombining the light and excitation beams by using energy of the light. In contrast, the cathodoluminescence (CL) method of the embodiment differs from the photoluminescence (PL) method in that in the cathodoluminescence (CL) method, the electron beams emitted from the electric field obtain energy while being accelerated by the electric field and then are injected into a light-emitting diode to generate light.

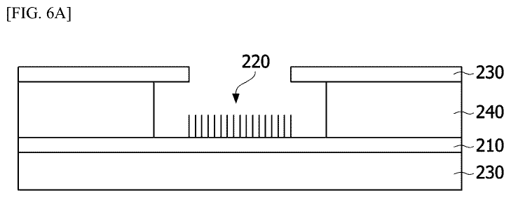

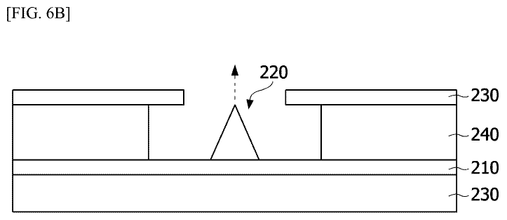

FIG. 5A is a view illustrating a mesh shape of the electron beam guide unit, FIG. 5B is a view illustrating a cross-sectional shape of the electron beam guide unit, FIG. 5C is a view illustrating a first modified example of FIG. 5A, FIG. 5D is a view illustrating a second modified example of FIG. 5A, FIG. 6A is a view illustrating the electron beam emitting unit, and FIG. 6B is a view illustrating a modified example of FIG. 6A.

With reference to FIG. 5A, the electron beam guide unit 300 may have a mesh shape in which the plurality of through-holes 310 is formed in a frame 311. An example is described in which the through-hole 310 has a quadrangular shape. However, the through-hole 310 may have various polygonal or circular shapes.

An area of the plurality of through-holes 310 of the electron beam guide unit 300 may be 80% to 95% of an overall area. The through-hole 310 may have a large area so that the electron beams may be uniformly emitted to the micro-light-emitting elements 100. However, in case that the area of the through-holes 310 is larger than 95%, an area of the electron beam guide unit 300 may decrease, which may degrade an effect of accelerating the electron beams.

With reference to FIG. 5B, the electron beam guide unit 300 may have a first surface 300a configured to face the electron beam emitting unit 200, and a second surface 300b configured to face the plurality of micro-light-emitting elements, and the second surface 300b may have a curvature. Therefore, an area of the second surface 300b may be larger than an area of the first surface 300a.

With this configuration, the electron beams having passed through the electron beam guide unit 300 are curved by an attractive force with the second surface 300b, such that the plurality of micro-light-emitting elements 100 may be uniformly irradiated with the electron beams.

With reference to FIG. 5C, the electron beam guide unit 300 may include the plurality of through-holes 310 elongated in one direction. That is, the electron beam guide unit 300 may have various shapes in addition to the mesh shape. The electron beam guide unit 300 may have an area corresponding to the plurality of light-emitting elements 100. However, the present invention is not necessarily limited thereto. For example, as illustrated in FIG. 5D, the electron beam guide unit 300 may include at least one through-hole 310 elongated in one direction. That is, an area of one through-hole 310 may be larger than an area of one light-emitting element or an area of the plurality of light-emitting elements.

According to the embodiment, it may be important to irradiate the plurality of micro-light-emitting elements 100 uniformly with the electron beams. Therefore, the emitter 220 may have a structure selected from various structures that uniformly emit electron beams.

With reference to FIG. 6A, the first electrode layer 210 may be disposed on the support substrate 10, and the emitter 220 may have a plurality of carbon nanotubes. The plurality of carbon nanotubes may be grown directly on the first electrode layer 210. However, the carbon nanotube may be grown on a separate substrate, and then the carbon nanotube may be transferred to the first electrode layer 210. In case that the separate substrate is a conductive substrate, the conductive substrate may be stacked on the first electrode layer 210.

The plurality of carbon nanotubes may be separated by the insulation layers 240. The gate electrode 230 may be disposed on the insulation layer 240. However, the position of the gate electrode 230 is not specially limited.

With reference to FIG. 6B, the emitter 220 may have a structure in which an end of the emitter 220 is formed to be pointy to make it easy to emit electrons. In addition, all publicly-known emitter configurations for emitting electrons may be applied to the configuration of the electron beam emitting unit 200.

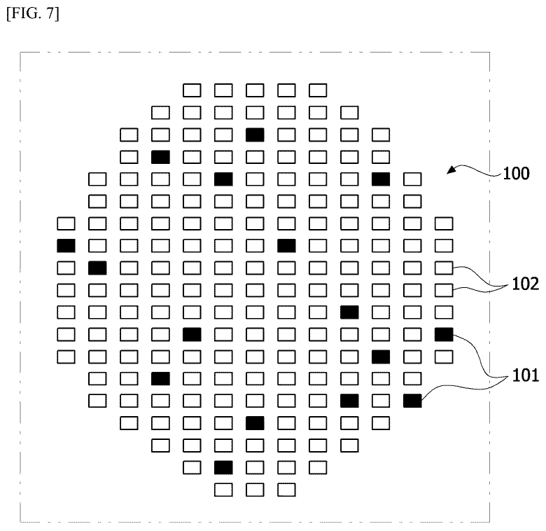

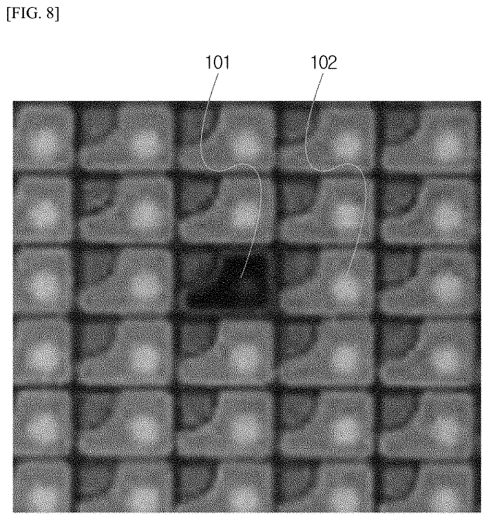

FIG. 7 is a view illustrating measured light-emitting intensities of the plurality of micro-light-emitting elements, and FIG. 8 is a photograph of the measured plurality of micro-light-emitting elements.

With reference to FIGS. 7 and 8, the control unit may create map data by collecting light-emitting intensities (light images) of the plurality of micro-light-emitting elements 100 collected by the optical detection unit. The control unit may determine an element 101, which has an intensity lower than a predetermined light-emitting intensity and does not emit light, as a defective element.

During a transfer process, only a normal element 102, which is not the defective element 101, may be selectively transferred. In addition, in case that the inspection is performed after the transfer process is completed, the defective element, which is determined as being defective, may be selectively removed or repaired.

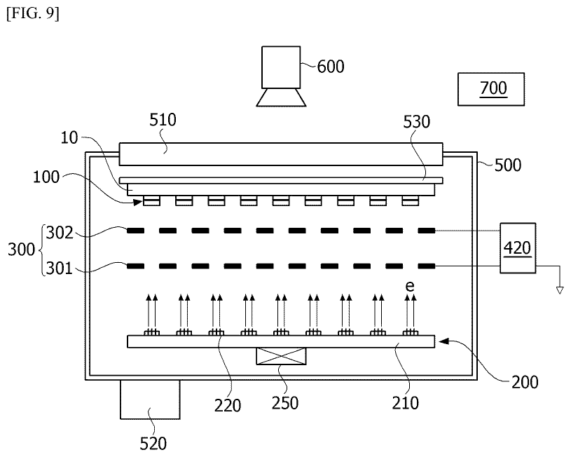

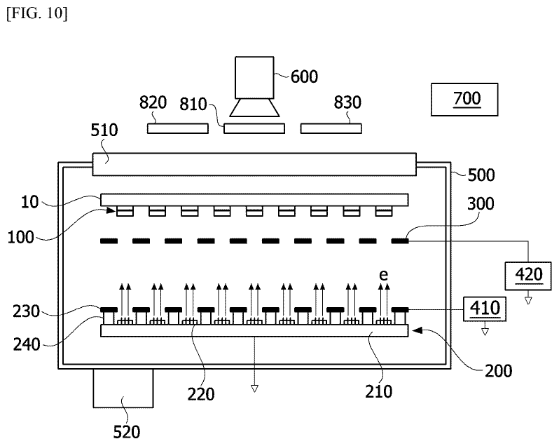

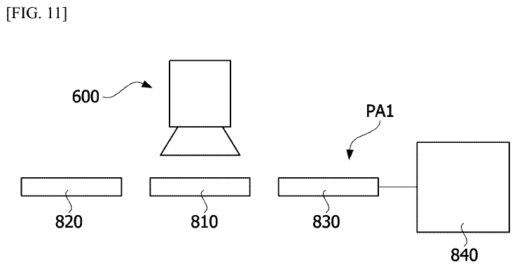

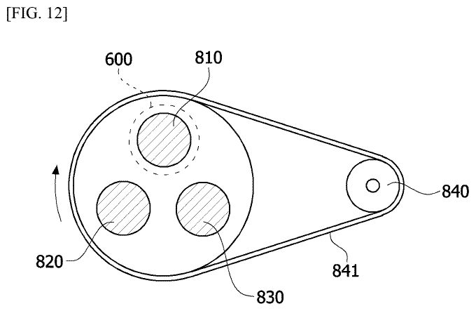

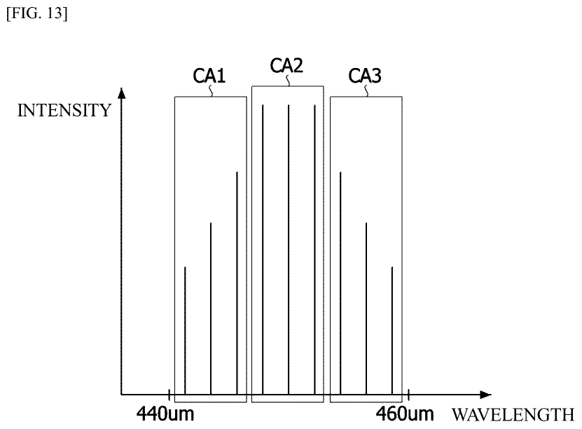

FIG. 9 is a conceptual view of an inspection apparatus according to a second embodiment of the present invention, FIG. 10 is a conceptual view of an inspection apparatus according to a third embodiment of the present invention, FIG. 11 is a view illustrating a filter array, FIG. 12 is a view illustrating a state in which the filter array is rotated, and FIG. 13 is a view illustrating a process in which a filter sorts wavelengths.

With reference to FIG. 9, in the inspection apparatus according to the embodiment, the electron beam guide unit 300 may be provided as a plurality of electron beam guide units 300 disposed in the vertical direction, thereby effectively accelerating the electron beams. In this case, a level of a voltage applied to a first electron beam guide unit 301 disposed at a lower side may be different from a level of a voltage applied to a second electron beam guide unit 302 disposed at an upper side. For example, the level of the voltage applied to the second electron beam guide unit 302 disposed at the upper side may be higher than the level of the voltage applied to the first electron beam guide unit 301 disposed at the lower side.

In addition, a vibration unit 250 may be disposed on the electron beam emitting unit 200 and vibrate the electron beam emitting unit 200. Therefore, directions of the emitted electron beams may be adjusted, which may further improve the uniformity of the electron beams. Alternatively, the first electron beam guide unit 301 and the second electron beam guide unit 302 may be vibrated.

The electron beam guide unit 300 or the stage 530 may move relative to each other to improve the uniformity. The movable member (not illustrated) may move the electron beam guide unit 300 or the stage 530 leftward and rightward, such that the micro-light-emitting elements 100, which overlap the electron beam guide unit 300 and are covered by the electron beam guide unit 300, may be exposed through the through-holes of the electron beam guide unit 300 and emit electron beams.

The electron beam emitting unit 200 may exclude the gate electrode. In this case, an electric field may be formed between the first electrode layer 210 and the electron beam guide unit 300, such that electrons may be discharged.

With reference to FIG. 10, the inspection apparatus according to the embodiment may filter only light beams in desired wavelength bands among the light beams emitted from the micro-light-emitting elements 100. For example, in case that a desired peak wavelength band is 423 nm in the blue micro-light-emitting element 100, blue light beams in other wavelength bands may be blocked by first to third filters 810, 820, and 830. Therefore, the micro-light-emitting element 100 having a desired wavelength band may be selected.

With reference to FIGS. 11 and 12, a filter array PAI may include a first filter 810 configured to selectively transmit a light beam in a first wavelength band among all the wavelength bands of the first light beam emitted from the active layers of the plurality of micro-light-emitting elements 100, a second filter 820 configured to selectively transmit a light beam in a second wavelength band different from the first wavelength band among all the wavelength bands of the first light beam, and a third filter 830 configured to selectively transmit a light beam in a third wavelength band. The plurality of filters 810, 820, and 830 may be selectively disposed below the optical detection unit 600 by a drive unit 840. The first light beam may be one of the light beams in the blue, green, and red wavelength bands.

With reference to FIG. 13, for example, the blue micro-light-emitting element may emit blue light having a peak in a wavelength band of 440 nm to 460 nm. The plurality of blue micro-light-emitting elements is grown on one wafer, but main peaks of the plurality of blue micro-light-emitting elements may be slightly different from one another because growth conditions are finely changed. In this case, an emission wavelength band of each of the blue micro-light-emitting elements 100 may be a band of about 5 nm. That is, a half-width of the main peak of the blue light emitted from each of the light-emitting elements may be very narrow.

For example, in case that 100 blue micro-light-emitting elements are manufactured, all the blue micro-light-emitting elements emit blue light. However, 32 blue micro-light-emitting elements may have wavelength bands of 440 nm to 445 nm, 38 blue micro-light-emitting elements may have wavelength bands of 446 nm to 450 nm, and the remaining 30 blue micro-light-emitting elements may have wavelength bands of 451 nm to 455 nm.

Therefore, in case that the first filter 810 is manufactured to have a transmission band CA1 of 440 nm to 445 nm, only the blue micro-light-emitting elements having wavelengths of 440 nm to 445 nm may be sorted by the first filter 810. That is, the elements having wavelength bands of 446 nm to 460 nm actually emit blue light, but the blue light is blocked by the first filter 810. Therefore, the optical detection unit 600 may detect that the elements do not emit light.

In case that the second filter 820 is manufactured to have a transmission band CA2 of 446 nm to 450 nm, only the blue micro-light-emitting elements 100 having wavelengths of 446 nm to 450 nm may be sorted by the second filter 820.

In addition, when the third filter 830 is manufactured to have a transmission band CA3 of 451 nm to 455 nm, only the blue micro-light-emitting elements 100 having wavelengths of 451 nm to 455 nm may be sorted by the third filter 830 and inspected. However, the number of filters and the range of the transmission wavelength band may be freely modified.

Therefore, among the plurality of blue micro-light-emitting elements 100 grown on one wafer, the elements having desired blue wavelengths may be finely sorted. Because the micro-light-emitting element 100 is used as the pixel of the display, a configuration in which the elements having the same peak wavelength among the blue wavelengths are disposed may be advantageous in terms of color uniformity.

In addition, the first to third blue micro-light-emitting elements 100 may be sorted and then mixed uniformly, and the mixed first to third blue micro-light-emitting elements 100 may be transferred to the panel. In this case, because the first blue micro-light-emitting elements (or the second and third blue micro-light-emitting elements) are not concentrated on any one portion, which may be advantageous in terms of color uniformity.

While the blue micro-light-emitting elements have been described above as an example, green micro-light-emitting elements and red micro-light-emitting elements may be sorted in the same way.

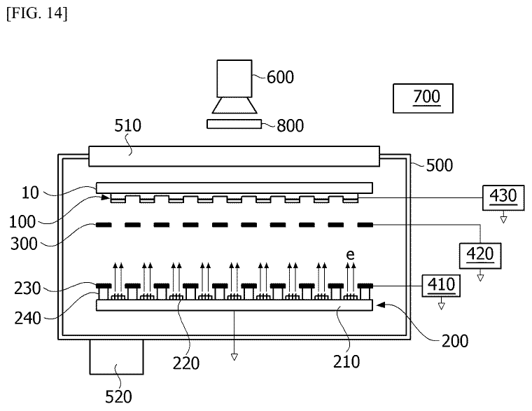

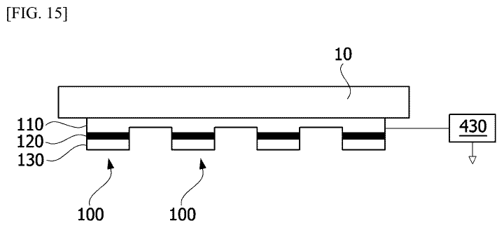

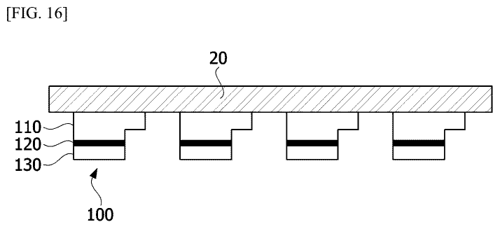

FIG. 14 is a conceptual view of an inspection apparatus according to a fourth embodiment of the present invention, FIG. 15 is a view illustrating a plurality of light-emitting elements in a state in which some of the plurality of light-emitting elements are connected, and FIG. 16 is a view illustrating a modified example of FIG. 15.

With reference to FIGS. 14 and 15, in the plurality of micro-light-emitting elements, the active layers 120 and the second conductive semiconductor layers 130 may be separated from one another, but the first conductive semiconductor layers 110 may be connected to one another. This light-emitting structure may be a structure in which light-emitting diodes are not yet completely manufactured.

In this case, a positive voltage is applied to the first conductive semiconductor layer 110 by a third power source unit 430, which may further accelerate the electron beams having passed through the electron beam guide unit 300. In this case, in case that a sufficient electric field is formed between the first conductive semiconductor layer 110 and the electron beam emitting unit 200, the electron beam guide unit 300 may be excluded.

With reference to FIG. 16, the plurality of micro-light-emitting elements 100 may be in a state of being completely transferred to a display panel 20. Even in case that the process of transferring the plurality of micro-light-emitting elements 100 is completed, an operation of inspecting a defective element may be required before the panel is completely assembled. In the embodiment, the micro-light-emitting elements may emit light in a contactless manner, such that the inspection may be performed even after the micro-light-emitting elements are completely transferred to the panel.

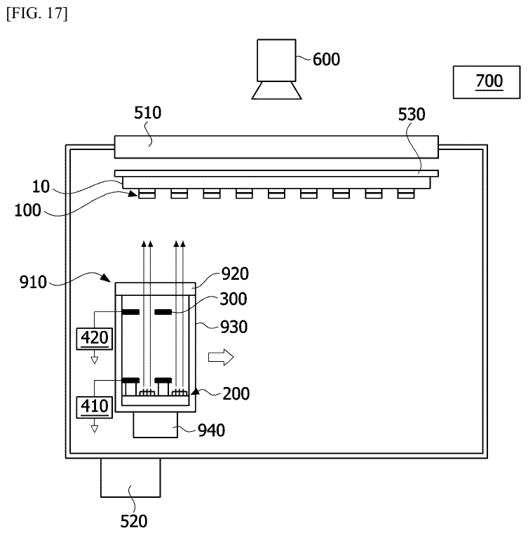

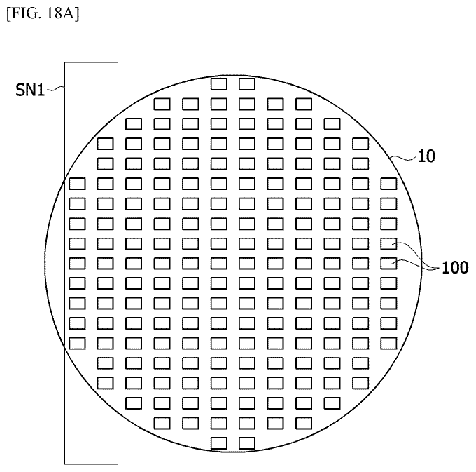

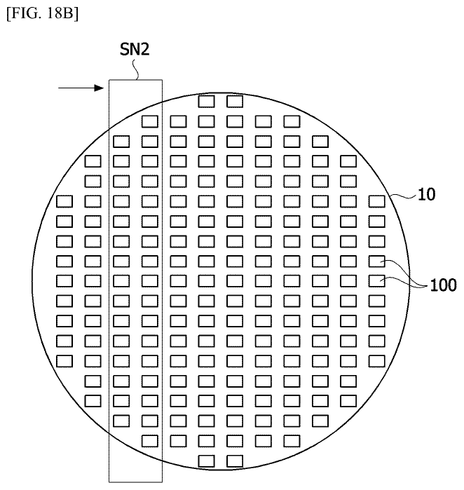

FIG. 17 is a conceptual view of an inspection apparatus according to a fifth embodiment of the present invention, and FIGS. 18A and 18B are views illustrating a process of scanning a linear inspection area.

With reference to FIG. 17, the inspection apparatus may perform the inspection by using an electron beam emitting module 910. The electron beam emitting module 910 may include a housing 930 configured to accommodate the electron beam emitting unit 200 and the electron beam guide unit 300. The electron beam emitting unit 200 and the electron beam guide unit 300 may be sized to the extent that the electron beam emitting unit 200 and the electron beam guide unit 300 may emit electron beams only to partial areas of the plurality of micro-light-emitting elements 100.

The housing 930 may include a transmission part 920 configured to emit electron beams only to partial areas of the light-emitting elements. The housing 930 may be moved in one direction by a movement module 940. With this configuration, an area of the electron beam emitting unit 200 and an area of the electron beam guide unit 300 may be reduced, and the inspection may be performed regardless of a size of a wafer.

With reference to FIGS. 18A and 18B, the electron beams may be emitted in a line shape by the electron beam emitting module 910, and emission areas SN1 and SN2 may allow the micro-light-emitting elements 100 to continuously emit light while moving in one direction in a linear scanning manner. However, the present invention is not necessarily limited thereto. A one o'clock area, a five o'clock area, a seven o'clock area, and an eleven o'clock area of the substrate 10 may be sequentially irradiated clockwise or counterclockwise with the electron beam emitted from the electron beam emitting module 910.

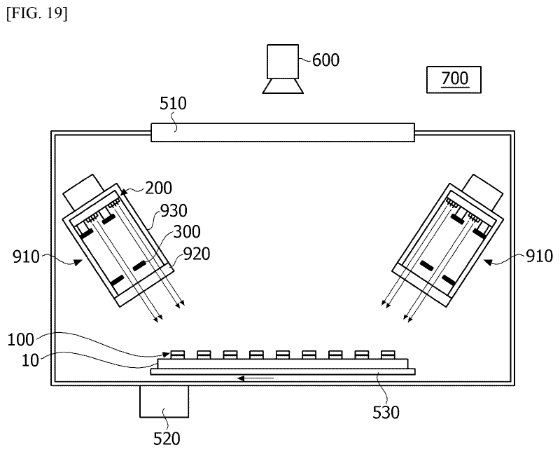

FIG. 19 is a conceptual view of an inspection apparatus according to a sixth embodiment of the present invention.

With reference to FIG. 19, a first electron beam emitting module 910 and a second electron beam emitting module 910 may be disposed to be inclined with respect to a line perpendicular to the stage 530. The entirety of the plurality of micro-light-emitting elements 100 may be irradiated with the electron beam emitted from the first electron beam emitting module 910 and the electron beam emitted from the second electron beam emitting module 910. The second electron beam emitting module 910 may be excluded as long as the entirety of the plurality of micro-light-emitting elements 100 may be irradiated with the electron beam emitted from the first electron beam emitting module 910.

With this configuration, the optical detection unit 600 may directly capture images of light beams emitted by the plurality of light-emitting elements. This structure may be suitable in case that a thickness of the substrate 10 is too large and an intensity of light emitted from the light-emitting element is low or in case that the substrate 10 does not appropriately transmit light, like a display panel substrate or a GaAs substrate.

The first electron beam emitting module 910 and/or the second electron beam emitting module 910 may emit electron beams only to partial areas of the plurality of micro-light-emitting elements. In this case, the stage 530 may move in the horizontal direction. Therefore, the plurality of micro-light-emitting elements 100 may emit light sequentially. Therefore, the control unit 700 may sequentially detect defective elements by analyzing light images acquired by the optical detection unit 600. Alternatively, the control unit 700 may detect the defective elements after the scanning process is entirely ended.

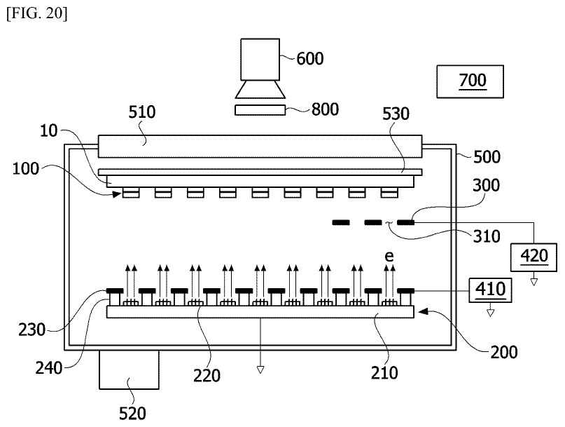

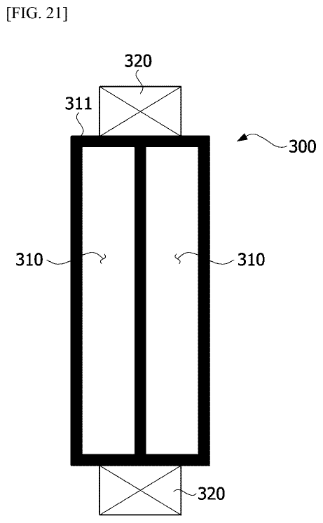

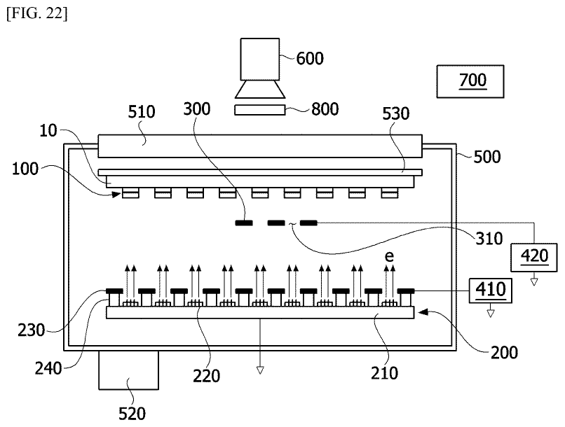

FIG. 20 is a conceptual view of an inspection apparatus according to a seventh embodiment of the present invention, FIG. 21 is a top plan view of an electron beam guide unit, and FIG. 22 is a view illustrating a state in which the electron beam guide unit is moved.

With reference to FIGS. 20 and 21, the inspection apparatus according to the embodiment includes the stage 530 on which the plurality of micro-light-emitting elements 100 is disposed, the electron beam emitting unit 200 configured to emit electron beams to the plurality of micro-light-emitting elements 100, the electron beam guide unit 300 disposed in a partial area between the electron beam emitting unit 200 and the plurality of micro-light-emitting elements 100, and the chamber 500 configured to create a vacuum therein.

The electron beam guide unit 300 may include at least one through-hole 310. In the embodiment, two rectangular through-holes 310 are described as an example. However, one through-hole 310 may be provided, or three or more through-holes 310 may be provided. In addition, the through-hole may have various shapes (a circular shape or a polygonal shape) instead of a rectangular shape.

The electron beam guide unit 300 may be disposed in a partial area between the electron beam emitting unit 200 and the plurality of micro-light-emitting elements 100 and moved in one direction by the movable members 320.

With reference to FIG. 22, the electron beams may be sequentially accelerated as the electron beam guide unit 300 is moved in one direction by the movable members 320. With this configuration, the electron beam may be relatively accelerated at a point at which the electron beam guide unit 300 moves in a state in which the entirety of the electron beam emitting units 200 emit the electron beams.

That is, because the entirety of the electron beam emitting units 200 emit electron beams, some of the normal light-emitting elements 100 may emit light. However, in case that the electron beam is not sufficiently accelerated, the light-emitting image may be relatively dark. Alternatively, because the electron beams do not effectively enter some of the normal light-emitting elements 100, the normal light-emitting elements 100 may not emit light. This light image may be treated as a light image that is not effective.

However, at the point at which the electron beam guide unit 300 is positioned, the sufficiently accelerated electron beam enters the light-emitting element, such that a relatively bright light image may be detected. Therefore, the electron beam guide unit 300 may accelerate electron beams sequentially while moving, and the light-emitting images may be sequentially acquired in the area in which the electron beams are accelerated, such that the normal elements may be detected. With this configuration, the inspection may be performed without constraint to the area of the substrate of the micro-light-emitting element.

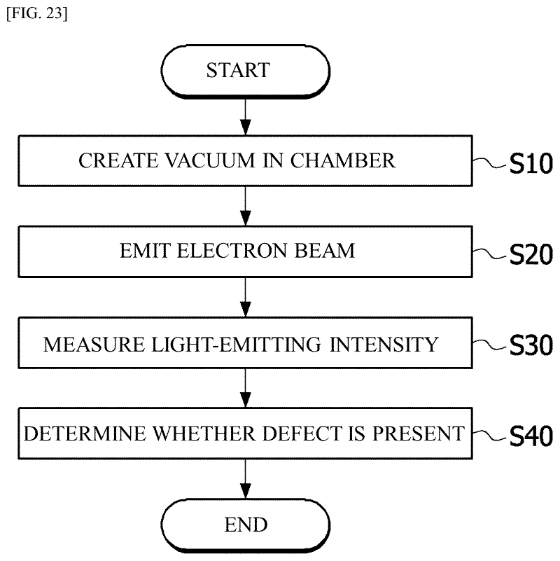

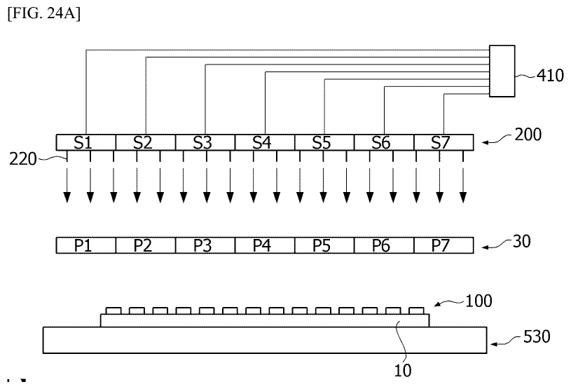

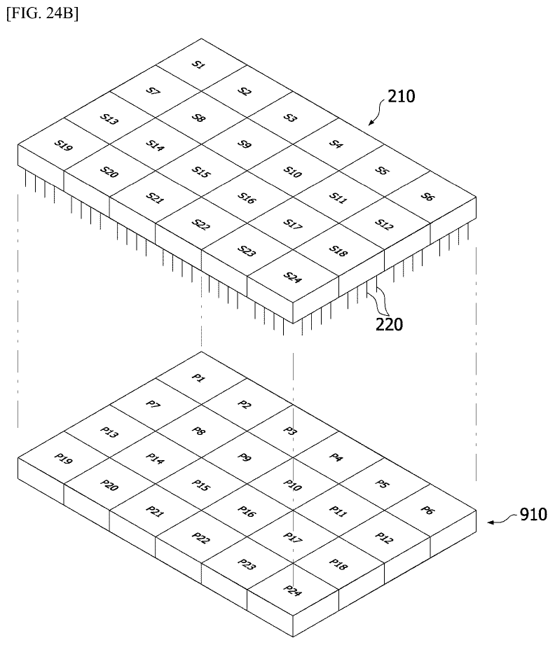

FIG. 23 is a flowchart illustrating an inspection method according to one embodiment of the present invention, FIG. 24A is a view illustrating a state in which an electron beam measurement unit measures uniformity of the electron beams, and FIG. 24B is a view illustrating a state in which a first electrode layer and the electron beam measurement unit are divided into a plurality of areas.

Referring to FIGS. 1 and 23, an inspection method according to the embodiment of the present invention may include: creating a vacuum in the chamber 500 (step S10); emitting electron beams to the micro-light-emitting elements 100 disposed in the chamber 500 (step S20); measuring light-emitting intensities of the micro-light-emitting elements 100 (step S30); and determining whether the micro-light-emitting elements 100 are defective (step S40).

The creating of the vacuum in the chamber 500 (step S10) may include adjusting the vacuum in the chamber 500 to 10⁻⁵ Torr or less by operating the vacuum pump when the micro-light-emitting element 100 is disposed in the chamber 500. When the vacuum in the chamber 500 is adjusted to 10⁻⁵ Torr or less, it is possible to prevent the electron beams from scattering, thereby preventing the occurrence of plasma.

The emitting of the electron beams to the micro-light-emitting elements 100 disposed in the chamber 500 (step S20) may include applying a high voltage of 3,000 V to 5,000 V with a pulse of 1 kHz or less to the electron beam emitting unit 200, and accelerating the electron beams by applying a positive voltage of 8,000 V to 12,000 V to the electron beam guide unit 300.

When the electron beams are emitted to the micro-light-emitting elements 100, the electron beams may collide with one another in the active layer, such that the electron-hole pairs may be generated. The generated electron-hole pairs may be restricted in the well layer by the barrier layer of the active layer. The restricted electrons and holes may be recombined to emit visible light.

The intensity of the visible light emitted from the micro-light-emitting element 100 may be proportional to the intensity (or density) of the electron beam. Therefore, the intensity (or density) of the electron beam may be adjusted to detect the light emitted from the micro-light-emitting element 100 and determine whether the micro-light-emitting element is defective.

The measuring of the light-emitting intensities of the micro-light-emitting elements 100 (step S30) may include acquiring, by the optical detection unit 600, images indicating that the plurality of micro-light-emitting elements 100 emit light. The optical detection unit 600 may be, but not necessarily limited to, a camera. Various detection devices capable of detecting whether the micro-light-emitting element 100 emits light may be applied without limitation.

The optical detection unit 600 may convert the collected light images into an electrical signal and then transmit the electrical signal to the control unit 700.

In this case, the filter 800 may selectively transmit only the light beams in some wavelength bands among the first light beams emitted from the light-emitting elements. The contents described with reference to FIGS. 10 to 13 may be applied to the detailed description thereof in an intact manner.

The determining of whether the micro-light-emitting elements 100 are defective (step S40) may include detecting the light emitted from the micro-light-emitting elements 100 and determining the micro-light-emitting element 100, which emits light with an intensity equal to or lower than a predetermined reference intensity, as a defective micro-light-emitting element.

According to the embodiment, the inspection method may include: between the creating of the vacuum (step S10) and the emitting of the electron beams (step S20), measuring intensities of electron beams in the plurality of emission areas of the electron beam emitting unit 200 disposed in the chamber 500; and adjusting the intensity of the electron beam in the emission area in which the intensity of the electron beam deviates from a predetermined intensity range among the plurality of emission areas.

Referring to FIGS. 24A and 24B, the measuring of the intensities of the electron beams may include measuring, by the electron beam measurement unit 30, the uniformity of the electron beams before the electron beams are emitted to the micro-light-emitting elements 100. The electron beam measurement unit 30 may be disposed between the electron beam emitting unit 200 and the stage 530 by the drive unit (not illustrated) during the measurement. When the measurement is completed, the electron beam measurement unit 30 may be moved away from the location between the electron beam emitting unit 200 and the stage 530.

The electron beam measurement unit 30 may be divided into the plurality of detection areas P1 to P24. The plurality of detection areas P1 to P24 may be disposed to be matched with the plurality of emission areas S1 to S24. Therefore, it is possible to determine the emission area in which the electron beams are non-uniform by using the values measured in the plurality of detection areas P1 to P24.

The adjusting of the intensity of the electron beam may include detecting an area in which the intensities of the electron beams are relatively non-uniform and adjusting the intensities of the electron beams so that the intensity of the electron beam in the corresponding area is matched with the predetermined reference range (or average intensity).

For example, the voltage level in the emission area may be raised for a point at which the intensity of the electron beam is low, and the voltage level in the emission area may be lowered for a point at which the intensity of the electron beam is high.

While the embodiments have been described above, the embodiments are just illustrative and not intended to limit the present invention. It can be appreciated by those skilled in the art that various modifications and applications, which are not described above, may be made to the present embodiment without departing from the intrinsic features of the present embodiment. For example, the respective constituent elements specifically described in the embodiments may be modified and then carried out. Further, it should be interpreted that the differences related to the modifications and alterations are included in the scope of the present invention defined by the appended claims.

1. An inspection apparatus comprising:
a stage on which a plurality of micro-light-emitting elements is disposed;
an electron beam emitting unit configured to emit electron beams to the plurality of micro-light-emitting elements;
an optical detection unit configured to acquire an image of light emitted from the plurality of micro-light-emitting elements;
an electron beam guide unit disposed between the electron beam emitting unit and the plurality of micro-light-emitting elements; and
a control unit configured to determine whether the plurality of micro-light-emitting elements is defective on the basis of the image of light acquired by the optical detection unit.

2. The inspection apparatus of claim 1, wherein the electron beam guide unit comprises at least one through-hole through which the electron beam passes.

3. The inspection apparatus of claim 2, wherein the electron beam guide unit has a mesh shape.

4. The inspection apparatus of claim 2, wherein at least one through-hole of the electron beam guide unit is elongated.

5. The inspection apparatus of claim 2, wherein the electron beam guide unit has an area corresponding to a partial area of the stage, and the electron beam guide unit is configured to move in one direction between the stage and the electron beam emitting unit.

6. The inspection apparatus of claim 1, wherein a ratio between a first distance between the electron beam emitting unit and the micro-light-emitting element and a second distance between the electron beam emitting unit and the electron beam guide unit (first distance: second distance) is 1:0.6 to 1:0.99.

7. The inspection apparatus of claim 1, wherein the electron beam guide unit comprises:
a first electron beam guide unit disposed between the electron beam emitting unit and the plurality of micro-light-emitting elements; and
a second electron beam guide unit disposed between the first electron beam guide unit and the plurality of micro-light-emitting elements.

8. The inspection apparatus of claim 1, wherein the electron beam emitting unit comprises:
an electrode layer;
a plurality of emitters formed on the electrode layer and configured to emit electrons toward the plurality of micro-light-emitting elements; and
a gate electrode disposed to be spaced apart from the electrode layer, and
wherein the emitter comprises a carbon nanotube.

9. The inspection apparatus of claim 8, wherein a level of a voltage applied to the electron beam guide unit is higher than a level of a voltage applied to the gate electrode.

10. The inspection apparatus of claim 1, wherein the plurality of micro-light-emitting elements each comprises:
a first conductive semiconductor layer;
a second conductive semiconductor layer; and
an active layer disposed between the first conductive semiconductor layer and the second conductive semiconductor layer, and
wherein the first conductive semiconductor layer, the active layer, and the second conductive semiconductor layer each emit light when irradiated with the electron beam.

11. The inspection apparatus of claim 10, comprising:
a filter configured to block some of light beams entering the optical detection unit,
wherein the filter transmits a first light beam emitted from the active layer and blocks a second light beam emitted from the first conductive semiconductor layer or the second conductive semiconductor layer.

12. The inspection apparatus of claim 10, comprising:
a filter array configured to block some of light beams entering the optical detection unit,
wherein the filter array comprises:
a first filter configured to selectively transmit a light beam in a first wavelength band among all wavelength bands of first light beams emitted from the active layers of the plurality of micro-light-emitting elements; and
a second filter configured to selectively transmit a light beam in a second wavelength band different from the first wavelength band among all the wavelength bands of the first light beams, and
wherein the first light beam is any one of a blue light beam, a green light beam, and a red light beam.

13. The inspection apparatus of claim 12, wherein the filter array comprises a drive unit configured to selectively dispose the first filter and the second filter on the optical detection unit.

14. The inspection apparatus of claim 1, comprising:
a vibration unit configured to vibrate the electron beam emitting unit.

15. The inspection apparatus of claim 2, wherein the stage or the electron beam guide unit moves in one direction, such that the micro-light-emitting element, which overlaps the electron beam guide unit, is exposed through the through-hole of the electron beam guide unit.

16. The inspection apparatus of claim 1, comprising:
a chamber in which the stage, the electron beam emitting unit, and the electron beam guide unit are disposed; and
a vacuum pump configured to create a vacuum in the chamber.

17. The inspection apparatus of claim 1, comprising:
a housing configured to accommodate the electron beam emitting unit and the electron beam guide unit; and
a movement module configured to move the housing,
wherein only some of the plurality of micro-light-emitting elements are irradiated with the electron beams emitted from the housing, and an emission area of the electron beam is moved in one direction by the movement module.

18. The inspection apparatus of claim 17, wherein the housing is disposed to be inclined with respect to an imaginary line perpendicular to the stage.

19. An inspection method comprising:
creating a vacuum in a chamber;
emitting electron beams to a plurality of micro-light-emitting elements disposed in the chamber;
measuring light-emitting intensities of the plurality of micro-light-emitting elements; and
determining whether the plurality of micro-light-emitting elements is defective,
wherein the electron beams are accelerated by an electron beam guide unit disposed between an electron beam emitting unit and the plurality of micro-light-emitting elements, and the electron beams are injected into the plurality of micro-light-emitting elements.

20. The inspection method of claim 19, wherein the measuring of the light-emitting intensities comprises selectively transmitting a light beam in a wavelength band among all wavelength bands of first light beams emitted from active layers of the plurality of micro-light-emitting elements.
